(19) United States
(12) Patent Application Publication
(10) Pub. No.: US 2003/0096490 A1
(43) Pub. Date: May 22, 2003

(54) Method of forming ultra shallow junctions

(76) Inventors: John Borland, South Hamilton, MA (US); Susan Felch, Los Altos Hills, CA (US); Ziwei Fang, San Jose, CA (US); Bon-Woong Koo, Palo Alto, CA (US)

Correspondence Address: Gary Loser, Varian Semiconductor, 35 Dory Lane, Gloucester, MA, 01930, US

(21) Appl. No.: 10/156,981

(22) Filed: May 29, 2002

Related U.S. Application Data
(60) Provisional application No. 60/339,052, filed on Nov. 16, 2001.

(51) Int. Cl. H01L 21/336; H01L 21/26; H01L 21/42; H01L 21/425

(52) U.S. Cl. 438/513; 438/528; 438/530

(57) ABSTRACT

A method for forming a shallow junction in a semiconductor wafer may include amorphizing the wafer to obtain a depth of end-of-range (EOR) defects that is smaller than a desired junction depth in a range of about 13 nm to about 50 nm, implanting a dopant material into the wafer at a selected dose and energy to produce the desired junction depth, and activating the dopant material by thermal processing of the semiconductor wafer at a selected temperature for a selected time consistent with low-temperature solid phase epitaxy (SPE) annealing to form the shallow junction. The control of the EOR depth through a preamorphizing implant to less than the junction depth provides for a low leakage junction and the low-temperature SPE anneal prevents diffusion of the dopant beyond the desired junction depth.

### RELATED APPLICATIONS

This application claims priority to, and incorporates by reference, the entire disclosure of U.S. Provisional Patent Application No. 60/339,052, filed on Nov. 16, 2001.

### FIELD

The methods and systems relate to forming shallow junctions in semiconductor wafers by ion implantation and, more particularly, to methods for low temperature annealing of shallow junctions.

### BACKGROUND

Ion implantation is a standard technique for introducing conductivity-altering dopant materials into semiconductor wafers. In a conventional ion implantation system, a desired dopant material is ionized in an ion source, the ions are accelerated to form an ion beam of prescribed energy, and the ion beam is directed at the surface of the wafer. The energetic ions in the beam penetrate into the bulk of the semiconductor material and are embedded into the crystalline lattice of the semiconductor material. Following ion implantation, the semiconductor wafer is annealed to activate the dopant material and provide damage recovery. Annealing involves heating the semiconductor wafer to a prescribed temperature for a prescribed time.

A well-known trend in the semiconductor industry is toward smaller, higher speed devices. In particular, both the lateral dimensions and the depths of features in semiconductor devices are decreasing. State of the art semiconductor devices require junction depths less than 300 angstroms and may eventually require junction depths on the order of 100 angstroms or less.

The implanted depth of the dopant material is determined by the energy of the ions implanted into the semiconductor wafer. Shallow junctions are obtained with low implant energies. However, the annealing process that is used for activation of the implanted dopant material and damage recovery causes the dopant material to diffuse from the implanted region of the semiconductor wafer. At high temperatures (900° C. to 1200° C.) thermal diffusion occurs but under certain conditions enhanced thermal diffusion mechanisms can also occur including oxygen-enhanced diffusion (OED), boron enhanced diffusion (BED), transient enhanced diffusion (TED), etc. As a result of such diffusion, junction depths are increased by as much as 50 Å to 500 Å by annealing. Additionally, high-temperature anneal may not be compatible with most high-k gate dielectrics that may be needed to meet shallow junction goals.

To counteract the increase in junction depth produced by annealing, the implant energy may be decreased, so that a desired junction depth after annealing is obtained. This approach provides satisfactory results, except in the case of very shallow junctions. A limit is reached as to the junction depth that can be obtained by decreasing implant energy, due to the diffusion of the dopant material that occurs during annealing. In addition, ion implanters typically operate inefficiently at very low implant energies.

Another approach uses a low temperature solid phase epitaxy (SPE) anneal to reduce diffusion. However, two main concerns with implementing low-temperature SPE are junction leakage and dopant activation. Since diffusion is reduced using SPE, the junction may not be formed deep enough to prevent the end-of-range (EOR) defects from being in the space charge region of the device and contributing significantly to junction leakage.

Current approaches used in the art do not provide a satisfactory process for fabricating shallow junctions of selected junction depth and sheet resistance, particularly where the required junction depth cannot be obtained simply by reducing the implant energy. Accordingly, a need exists for improved methods for fabricating shallow junctions in semiconductor wafers.

### SUMMARY

In accordance with the method described herein, an embodiment of a method to provide low resistivity shallow junctions may comprise amorphizing a region of a semiconductor material to a first depth, doping the region to obtain a junction depth greater than the first depth and annealing the material at a temperature consistent with solid phase epitaxy (SPE) regrowth of the material so as to activate the junction.

In one embodiment, a preamorphizing implant (PAI) using silicon, germanium, antimony, indium, or other ion species at implant energies less than about 12.0 keV amorphizes the region. One embodiment uses beam-line implantation with B¹¹ or BF₂ ions at implant energies in a range of 1 to 2 keV to provide junction depths of about 16 nm to 26 mn. One embodiment utilizes plasma doping with BF₃ or B₂H₆ for doping to obtain shallow junctions. In one embodiment, the annealing temperature is in a range of about 550° C. to about 700° C.

### BRIEF DESCRIPTION OF THE DRAWINGS

The following figures depict certain illustrative embodiments in which like reference numerals refer to like elements. These depicted embodiments are to be understood as illustrative and not as limiting in any way.

FIG. 1 is a plot of amorphous layer depth versus implant energy;

FIG. 2 provides a flow chart of the process for providing shallow junctions with low resistivity;

FIG. 3 shows secondary ion mass spectrometry (SIMS) profiles that may be obtained using the process of FIG. 1 for a range of plasma doping energy levels followed by a SPE anneal at 580° C. for 15 minutes;

FIG. 4 illustrates a plot of junction depth versus preamorphizing implant energy; and

FIG. 5 illustrates a plot of junction leakage that may be obtained using the process of FIG. 2.

### DETAILED DESCRIPTION OF THE PREFERRED EMBODIMENT

The need for shallow junctions has increased as semiconductor device dimensions have decreased. Published guidelines of the International Technology Roadmap for Semiconductors (2001) indicate that by 2010, it can be expected that the 50 nm Technology Node (TN) production devices can have transistor gate lengths of less than 25 nm and shallow junction depths (Xⱼ) between 7 nm and 12 nm. Additionally, sheet resistances in the range of 830 ohms/sq can be required. The International Technology Roadmap for Semiconductors (ITRS) guidelines, as shown in Table 1, provide the following targets:

TABLE 1
TECHNOLOGY NODE

| | 130 nm | 100 nm | 70 nm | 50 nm | 35 nm |
|---|---|---|---|---|---|
| Target Year | 2001 | 2003 | 2006 | 2010 | 2013 |
| Junction Depth, Xⱼ (nm) | 27-45 | 19-31 | 12-19 | 7-12 | 5-9 |
| Sheet Resistance, | 400 | 550 | 830 | 830 | 940 |
| Rs (ohms/sq) | | | | | |
| Dopant Level | 5E19 | 8E19 | 1E20 | 1.5E20 | 2E20 |
| (atoms/cm3) | | | | | |

Typically, shallower junctions can be obtained by decreasing implant energies. However, a limit may be reached as to the junction depth that can be obtained by decreasing implant energies, due to the diffusion of the dopant material that occurs during annealing. Additionally, current implantation equipment may not be efficient at low energies. One approach may be to reduce diffusion of the dopant material by using a low temperature 550° C.-700° C. solid phase epitaxy (SPE) anneal. It is known that the SPE recrystallization rate increases with temperature, e.g., at 500° C., 600° C. and 700° C., the respective rates are approximately 0.1 Å/sec, 10.0 Å/sec and 350 Å/sec. Thus, higher temperatures provide a quicker recrystallization rate.

With SPE annealing and no dopant diffusion/movement of the implanted dopant atoms, beam-line implantation can be extended down to the sub-50 nm TN and plasma implantation down to the sub-25 nm TN. Otherwise, beam-line can only be extended to the 100 nm TN and may need to be replaced at the 70 nm TN because of high-temperature dopant diffusion. Tables 2 and 3, for high-temperature annealing and low-temperature annealing, respectively, illustrate the implant energy required to achieve the desired ITRS Xⱼ implant junction depth.

TABLE 2
TECHNOLOGY NODE
Junction Depth from High-Temperature Diffusion/Annealing

| | 130 nm | 100 nm | 70 nm | 50 nm | 35 nm |
|---|---|---|---|---|---|
| Dopant Level/cm3 | 5E19 | 8E19 | 1E20 | 1.5E20 | 2E20 |
| Dose Range | 0.5-1E15 | 0.5-1E15 | 0.5-1E15 | Boron Solid | BSS |
| | | | | Solubility | |
| | | | | (BSS) | |
| B¹¹ (0.3% energy contamination) | <1 keV | <100 eV | — | — | — |
| B¹¹ (No energy contamination) | 0.7-1.3 keV | 300-800 eV | <300 eV | — | — |
| BF₂ (0.3% energy contamination) | 1.9-4.8 keV | 0.2-2.2 keV | <200 eV | — | — |
| BF₂ (No energy contamination) | 3.5-6.5 keV | 1.5-4.0 keV | <1.5 keV | — | — |
| PLAD | 1.2-2.5 kV | 0.4-1.7 kV | <400 V | — | — |

TABLE 3
TECHNOLOGY NODE
As-Implanted Junction for Low-Temperature SPE Annealing

| | 130 nm | | 100 nm | | 70 nm | | 50 nm | | 35 nm | |
|---|---|---|---|---|---|---|---|---|---|---|
| Dopant Level/cm3 | 5E19 | | 8E19 | | 1E20 | | 1.5E20 | | 2E20 | |
| Dose Range | 0.5-1E15 | | 0.5-1E15 | | 0.5-1E15 | | 0.5-1E15 | | 5E15 | |
| Ge-PAI | 11-21 | keV | 10-14 | keV | 6-10 | keV | 3-6 | keV | 2.5-5 | keV |
| Si-PAI | 9-16 | keV | 7-10 | keV | 4-7 | keV | 2-4 | keV | 2-3 | keV |
| B¹¹ (0.3% energy contamination) | 0.5-1.3 | KeV | <500 | eV | — | | — | | — | |
| B¹¹ (No energy contamination) | 1-1.7 | keV | 0.6-1.1 | keV | 300-600 | eV | 150-300 | eV | 80-200 | eV |
| BF₂ (0.3% energy contamination) | 3-6.5 | keV | 1.8-3.7 | keV | 0.2-1.7 | keV | <200 | eV | — | |
| BF₂ (No energy contamination) | 5-8.3 | keV | 3-5.5 | keV | 1.5-3 | keV | 0.75-1.5 | keV | 0.4-1 | keV |
| PLAD | 1.6-3 | kV | 1.2-2 | kV | 0.5-1.2 | kV | 200-600 | V | 100-300 | V |

The data in Table 2 assumes an 8.0 nm diffusion in the as-implanted junction depth due to high-temperature annealing and TED (transient enhanced diffusion), which can vary between 5 and 50 nm. Table 3 assumes no diffusion due to low-temperature annealing. In Table 3, dose ranges are shown for those cases for which experimental data is available. With plasma doping (PLAD) and high-temperature annealing, 70 nm node shallow junctions can be achieved, while with low temperature annealing, sub-35 nm TN can be realized. If, however, SPE can be used, then energy-contamination-free beam-line B¹¹ implant energies can be increased to 1.7 keV for 130 nm node, and ultra-low implant energies, i.e., 250 eV or less, may not be needed until the 50 nm TN.

The use of low-temperature SPE anneal can have an additional incentive in that higher-k gate dielectrics may be needed at the 70 nm to 100 nm TN. The high-k amorphous deposited gate dielectric materials may crystallize at temperatures above 750° C., thus degrading the dielectric material property. Thus low-temperature SPE anneal may be preferred for high-k gate material temperature compatibility.

Preamorphizing implant end-of-range (EOR) defects may form if the silicon has been amorphized during ion implantation. It is known that if EOR defects exist in a space charge region of a junction they may cause high leakage currents. Thus, it may be necessary to form the junction deep enough to maintain the EOR defects within the junction. Current methods rely on thermal diffusion and enhanced diffusion by TED, OED and BED resulting from high-temperature annealing to form the junction deep enough to limit leakage currents. Current methods may also rely on high temperatures to anneal out implant-induced defects. However, as was previously noted, the various thermally enhanced diffusion methods may require the use of ultra-low energy to obtain the ITRS guideline junction depths.

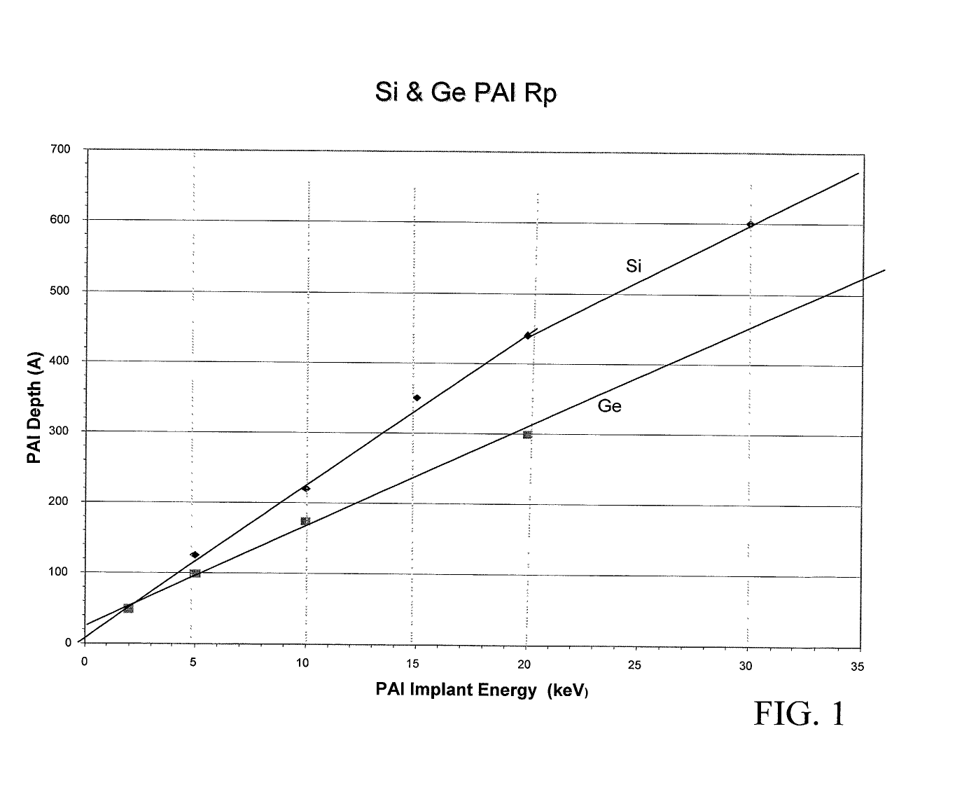

In the present method, a preamorphizing implant (PAI) may place and/or position the EOR defects at a desired depth compatible with the desired junction depth. The PAI process is well known in the art to minimize implantation channeling for abrupt and shallow junctions and may reduce diffusion. PAI also can enhance dopant activation above the dopant solubility limit in silicon. While, PAI typically can be combined with Rapid Thermal Annealing (RTA) for higher keV implant energies, no benefit can be seen for implant energies below about 1.0 keV. FIG. 1 provides a range of implant energies and corresponding EOR depths for silicon (Si) and germanium (Ge) PAI. As can be seen from FIG. 1, the EOR depths can be within the range of the junction depths required for the ITRS 50 nm node technology. Referring back to Table 3, it can be seen that the implant energies for forming the various ITRS shallow junctions can be increased should PAI and SPE be used. Without PAI, SPE may result in high sheet resistance (Rs). To achieve low Rs and good dopant activation, PAI may be necessary.

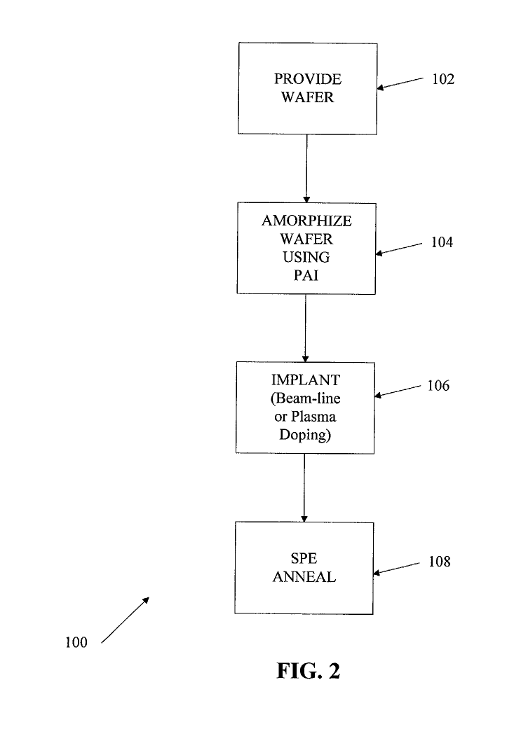

Referring now to FIG. 2, there is shown a flow chart of the method (100) used to provide shallow junctions with low resistivity. A Czochralski (Cz) grown silicon wafer can be provided (102) and a PAI can be performed on the wafer (104). It is to be understood that other wafer types, e.g., float zone (FZ), epitaxial silicon (EPI) and silicon-on-insulator (SOI), also can be provided. The PAI may be a Si, Ge, or other species of PAI, such as indium (In), antimony (Sb), etc., of the energy ranges and doses shown in Table 3, but noting that higher atomic masses may require higher implant energies. The Ge PAI may provide a smoother amorphous/crystalline interface, which may result in less leakage for a given average EOR depth.

The wafer then can be doped with boron (B¹¹ or BF₂) using beam-line implantation, or with boron (BF₃ or B₂H₆) using PLAD (106) in the energy ranges and doses shown in Table 3. Activation of the implant can be achieved using a low-temperature SPE anneal (108). Temperature ranges of about 550° C. to about 625° C. have been attempted with satisfactory results. The combination of PAI, as illustrated in FIG. 1, and beam-line implantation and/or PLAD within the ranges of implant energies and doses shown, followed by a low-temperature SPE anneal, can result in the shallow junction depths and low sheet resistances shown in Table 1.

The amorphous layer needed for SPE can also be produced using an amorphizing dopant implant only. As an example, for BF₂, B has a mass of 11 and F has a mass of 19 so F can amorphize the silicon lattice and its implanted range will be less than B, so the electrical dopant junction depth of B will be deeper than the F. Considering other dopants such as As (arsenic—mass of 75) or Sb (antimony—mass of 122), once the dopant concentration in the silicon lattice exceeds mid-E18/cm³, amorphization can occur and so the dopant atoms that are deeper at the lower concentration will form the electrical junction deeper.

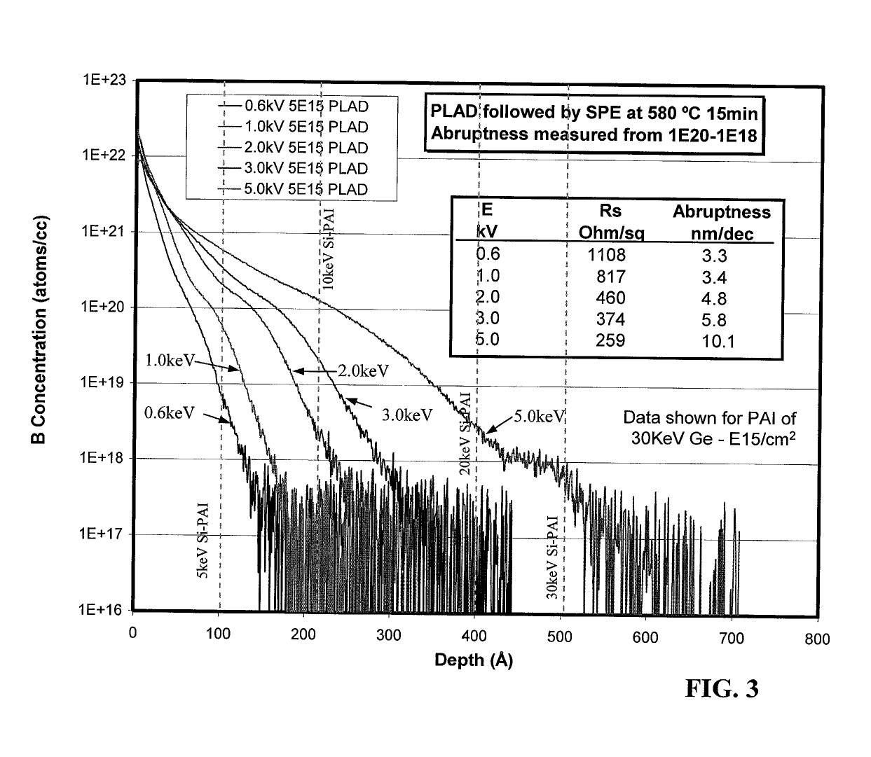

FIG. 3 provides secondary ion mass spectrometry (SIMS) profiles for a range of PLAD energy levels followed by a SPE anneal at 580° C. for 15 minutes. The PAI for the data in FIG. 3 is 30 keV Ge, 1E15/cm². As is known for such profiles, FIG. 3 shows the junction depth Xj increasing with increasing implant energy. FIG. 3 also illustrates the EOR depth for various Si PAI energy levels. Choosing a 2.0 keV, 5E15 PLAD implant as an example, it can be seen that Xj=18 nm, as measured at 1E+19/cm³. The PAI EOR can be less than Xj to provide a low leakage junction, as previously described. For the example selected, FIG. 3 shows a 5 keV Si PAI providing an EOR depth of approximately 10 nm and a 10 keV Si PAI providing an EOR of approximately 21 nm. The sheet resistance Rs is found to be 460 ohm/sq.

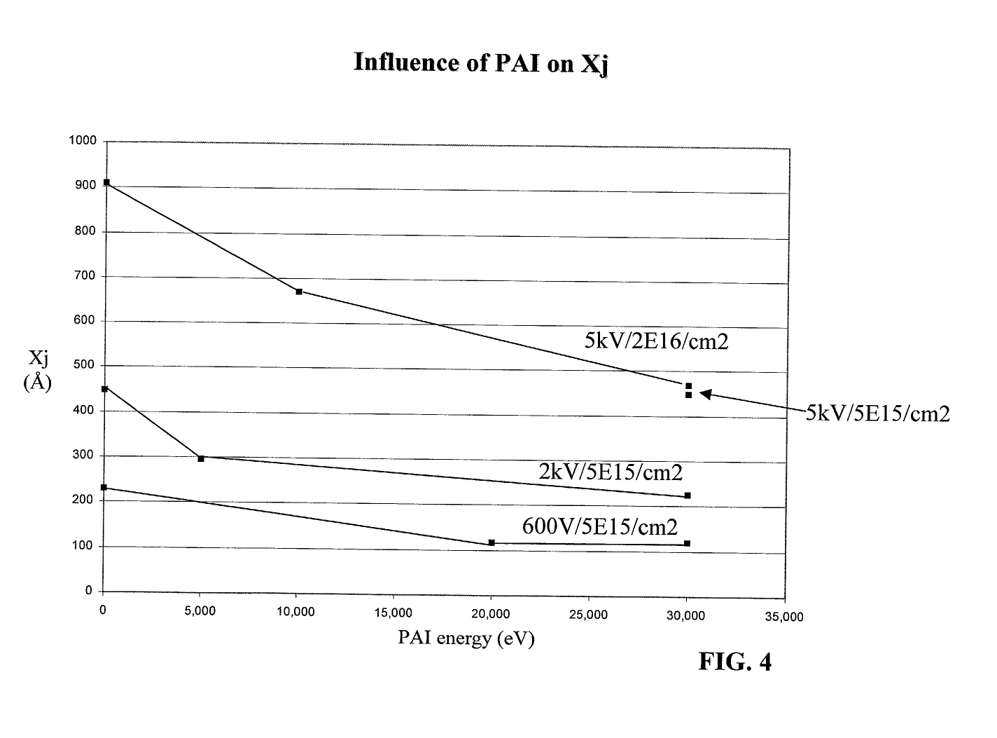

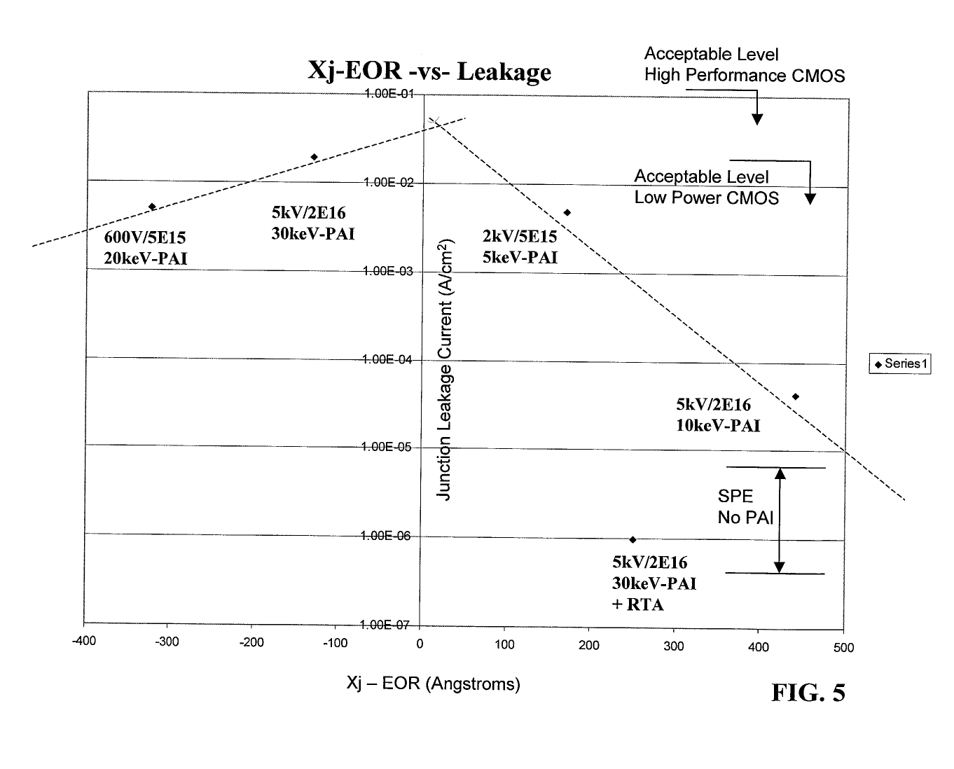

FIGS. 4 and 5 illustrate the impact that the process of FIG. 2 may have on junction depth and leakage, respectively. FIG. 4 is a plot of junction depth, Xj, versus PAI energy levels for four different PLAD implant energies/doses. The plot at the implant energies/doses shows Xj decreases with increasing PAI energies. Also, for any given PAI energy level, Xj increases with increasing implant energy/dose.

In FIG. 5, the horizontal axis is the difference between the junction depth and the PAI end of range damage (Xj-EOR) and the vertical axis is diode leakage current (A/cm²). The plotted points correspond to similarly labeled points in FIG. 4. What can be seen is that good leakage can be obtained with Si PAI of 10 keV and implant energy/dose of 5 keV/2E16/cm², and that all the leakage values are within the acceptable level required for both high performance (<2E-1 A/cm²) and low power (<2E-2 A/cm²) logic devices. The corresponding junction depth from FIG. 4 is approximately 680 angstroms. Thus, a high quality, low resistivity, ultra shallow junction can be formed using the methods described herein at implant energy levels consistent with current efficient implant technology.

While the methods and systems have been disclosed in connection with the preferred embodiments shown and described in detail, various modifications and improvements thereon will become readily apparent to those skilled in the art. For example, beam-line implantation and PLAD may include n-type doping in addition to the p-type doping described herein. For n-type doping using PLAD, the wafer can be doped with AsH₃ or PH₃. Using beam-line implantation, the wafer can be doped with As+, P+, or Sb. Accordingly, the spirit and scope of the present methods and systems is to be limited only by the following claims.

What is claimed is:

1. A method of forming a junction in a semiconductor material, comprising:
amorphizing a region of the material to a first depth;
doping the region to obtain a junction depth greater than the first depth; and
annealing the material at a temperature consistent with solid phase epitaxy (SPE) regrowth of the material so as to activate the junction.

2. The method of claim 1, wherein amorphizing comprises a preamorphizing implant (PAI).

3. The method of claim 2, wherein the PAI is one of an ion species including silicon, germanium, indium and antimony.

4. The method of claim 2, wherein the PAI energy is less than about 12.0 keV.

5. The method of claim 4, wherein the annealing temperature is in a range of about 550° C. to about 750° C.

6. The method of claim 2, wherein the annealing temperature is in a range of about 550° C. to about 750° C.

7. The method of claim 1, wherein doping comprises one of beam-line implantation and plasma doping (PLAD).

8. The method of claim 7, wherein ions are extracted from a plasma comprised of one of BF₃, B₂H₆, AsH₃ and PH₃.

9. The method of claim 8, wherein PLAD comprises implanting at energies in a range of about 200 eV to 2.0 keV.

10. The method of claim 7, wherein beam line implantation comprises implanting one of B¹¹ ions, BF₂ ions, As+ ions, P+ ions and Sb ions.

11. The method of claim 10, wherein beam line implantation comprises implanting at energies in a range of about 200 eV to 2.0 keV.

12. The method of claim 7, wherein amorphizing comprises a preamorphizing implant (PAI).

13. The method of claim 12, wherein the PAI is one of an ion species including silicon, germanium, indium and antimony.

14. The method of claim 12, wherein the PAI energy is less than about 12.0 keV.

15. The method of claim 14, wherein:
plasma doping comprises extracting ions from a plasma comprised of one of BF₃, B₂H₆, AsH₃ and PH₃; and
beam line implantation comprises implanting one of B¹¹ ions, BF₂ ions, As+ ions, P+ ions and Sb ions at energies in a range of about 200 eV to 2.0 keV.

16. The method of claim 15, wherein the annealing temperature is in a range of about 550° C. to about 750° C.

17. The method of claim 1, wherein the annealing temperature is in a range of about 550° C. to about 750° C.
